(19) United States
(12) Patent Application Publication
(10) Pub. No.: US 2026/0299058 A1
(43) Pub. Date: Oct. 1, 2026

(54) IMPROVED SPECTROMETER OR IMAGING ASSEMBLY

(71) Applicant: NPL MANAGEMENT LIMITED, Teddington Middlesex (GB)

(72) Inventors: Ian Gilmore, Surrey (GB); John Gallop, Greater London (GB); Ling Hao, Greater London (GB); Kewen Pan, Teddington Middlesex (GB)

(73) Assignee: NPL MANAGEMENT LIMITED, Teddington Middllesex (GB)

(21) Appl. No.: 19/165,260

(22) PCT Filed: Mar. 14, 2024
(86) PCT No.: PCT/GB2024/050690

§ 371 Date: Sep. 15, 2025

(30) Foreign Application Priority Data
Mar. 14, 2023 (GB) 2303717.9

(51) Int. Cl. G01R 33/32; H01J 49/42

(52) U.S. Cl. CPC G01R 33/326; H01J 49/425

(57) ABSTRACT

A spectrometer assembly comprises a spectrometer disposed in an ambient temperature environment; a SQUID microwave receiver disposed in a cryogenic enclosure; an impedance matching unit disposed between the spectrometer and the SQUID receiver; a signal up-conversion unit, disposed between the spectrometer and the SQUID receiver. The spectrometer may be a mass spectrometer, preferably an Orbitrap^{(RTM)} mass spectrometer, or a spectrometer using radiofrequency detection of current. There is also disclosed an imaging assembly comprising: an imaging device disposed in an ambient temperature environment; a SQUID microwave receiver disposed in a cryogenic enclosure; an impedance matching unit disposed between the imaging device and the SQUID receiver; a signal up-conversion unit, disposed between the imaging device and the SQUID receiver.

### TECHNICAL FIELD

The present invention relates to improvements in or relating to spectrometer and imaging assemblies and in the preferred embodiments to the improved detection of a radio frequency signal emerging from an ion detection apparatus, such as a mass spectrometer, or any other spectrometer using a coil pick-up method of current at radiofrequencies. The preferred embodiments are directed to mass spectrometers and methods of operating a mass spectrometer, preferably an Orbitrap^{(RTM)}.

### BACKGROUND TO THE INVENTION

With growing urgency over recent decades, metrology is moving towards the nanoscale, reflecting emphasis on micro- and nano-scale electronics as well as probing singe cells in biological systems. A new metrology capability has arisen based on developments in quantum mechanics, which enables single entities to be detected. These can be atoms, photons, radioactive particles, electrons or even phonons.

Orbitrap^{(RTM)} mass spectrometers are widely used, such as in applications ranging from detection of drug metabolites to proteomics and metabolomics. However, they all observe similar challenges in relation to sensitivity and dynamic range.

They can be used in particular for cancer metabolism, cancer biomarker discovery, infection assessment (viral, mycobacterial, parasitic), neurobiology and olfaction, evolution and Drosophila development, skin disease, Down's Syndrome, immunology (including immunological response), and sex genetics disorders, among others. All of these applications require greater sensitivity and improved signal-to-noise to achieve greater biological insight.

### SUMMARY OF THE PRESENT INVENTION

The present invention is directed to a quantum mechanical superconducting device and detection of radio frequency signals emerging from an ion detection apparatus, such as a mass spectrometer, or any other spectrometer using a coil pick-up method of current at radiofrequencies.

According to an aspect of the present invention, there is provided a spectrometer assembly comprising:
a spectrometer disposed in an ambient temperature environment;
a SQUID microwave receiver disposed in a cryogenic enclosure; and
an impedance matching unit disposed between the spectrometer and the SQUID receiver.

The assembly in some preferred embodiments also comprises a signal up-conversion unit, disposed between the spectrometer and the SQUID receiver.

The spectrometer may be a mass spectrometer with detection using an image charge current, preferably an electrostatic trap such as an Orbitrap mass spectrometer. Specifically, the Orbitrap mass spectrometer is an ion trap mass analyser comprising an outer barrel-like electrode and a coaxial inner spindle-like electrode that traps ions in an orbital motion around the spindle. Image current from the trapped ions is detected and converted to a mass spectrum by first using a Fourier transform of time domain of the harmonic to create a frequency signal which is converted to mass.

In other embodiments, the spectrometer is any spectrometer using a coil pick-up method of current at radiofrequencies.

According to an aspect of the present invention, there is provided a mass spectrometer comprising:
an electrostatic ion trap mass spectrometer disposed in an ambient temperature environment;
a SQUID microwave receiver disposed in a cryogenic enclosure; and
an impedance matching unit disposed between the imaging device and the SQUID receiver.

Optionally, the mass spectrometer may include a signal up-conversion unit, disposed between the imaging device and the SQUID receiver.

The spectrometer device may be a magnetic resonance imaging (MRI) device.

Advantageously, the SQUID provides a first, low noise, amplification stage in the assembly; a second stage being provided by an amplifier disposed in a cryogenic enclosure.

Preferably, the second stage amplifier is a high electron mobility transistor (HEMT) cryogenic amplifier, preferably a 6 GHz amplifier.

The assembly preferably comprises a signal processing unit coupled to an output of the SQUID and disposed in an ambient temperature environment.

The SQUID may be a microwave SQUID based on Josephson junctions using superconducting nano-constrictions. In other embodiments, the SQUID is a microwave SQUID based on Josephson junctions using superconducting tunnel junctions.

In the preferred embodiments, the SQUID is held in a cryogenic enclosure at around 4K.

The SQUID may comprise niobium (Nb) superconducting thin films, typically 50 to 200 nm in thickness, exhibiting superconducting transition temperatures between 8.2 and 9.0 K.

The superconducting thin films are advantageously patterned into coplanar waveguide structures, with microwave resonators in the frequency range from 1 GHz to 30 GHz

The preferred embodiments apply a quantum mechanical superconducting device (SQUID) to the detection of a radio frequency signal emerging from a mass spectrometer (or similar device). The result is the ability to detect a single ion of a particular mass-to-charge (m/z), among a signal from many ions at different mass-to-charges.

While the application of a SQUID to mass spectrometry is not straightforward, as explained below, the inventors have been able to demonstrate significant improvement in Mass Spectrometry sensitivity. This will enable major breakthroughs in understanding of single cell proteomics, single cell metabolomics and drug discovery, all of which are critical for future health and the impact on quality of life.

The preferred embodiments comprise a modified Orbitrap with a custom SQUID, structured such that ions entering the Orbitrap can be detected with single ion detection sensitivity using the quantum SQUID. The inventors have established that the Orbitrap requires around 10 ions for detection, which can lead to over a 10-fold increase in sensitivity compared to conventional analogue detection in an Orbitrap. Furthermore, they have established that at low counts, noise is dominated by thermal noise from the amplifier. The quantum system would also have a lower noise floor, increasing dynamic range from four orders of magnitude to five orders of magnitude. This would be very significant for proteomics owing to the massive biological dynamic range in protein abundance.

As is described below, the Orbitrap mass spectrometer is an ion trap mass analyser comprising an outer barrel-like electrode and a coaxial inner spindle-like electrode that traps ions in an orbital motion around the spindle. Image current from the trapped ions is detected and converted to a mass spectrum by first using a Fourier transform of time domain of the harmonic to create a frequency signal which is converted to mass.

For biological imaging applications the signal intensities are often dominated by thermal noise from the analogue detection circuitry.

The teachings herein demonstrate a structure and method by which a SQUID can be utilised in broadband mode in mass spectrometry. The teachings herein provide for increased detection sensitivity of ions during mass spectroscopy and increased dynamic range, with increases in performance and speed as a result thereof. This can allow greater use in important technologies, including in the study of proteins (proteomics) and metabolomics studies. There are multiple uses for instruments for high resolution mass spectrometry with single-ion sensitivity. The most likely field that can benefit is that of life sciences and health, specifically in drug discovery and the study of analysis of metabolites and proteins. The teachings herein can also be applied to many other fields, including semiconductor, battery technologies, environmental and food safety analysis.

In particular, it is expected that the system and method can address the challenges with existing mass spectrometers and provide a material gains in sensitivity as well as providing a 10-fold or greater increase in dynamic range. This will allow for a reduction in sample volumes, thus enabling the analysis of smaller biological samples including individual cells in culture.

The higher dynamic range possible with the system and method taught herein can offer much greater coverage of low abundant molecules in complex samples. A reduction in sample consumption can also have a material impact on instrument maintenance and long-term stability, advantageous to high throughput applications.

The developments available with the apparatus and method taught herein can provide improved Orbitrap-based mass spectroscopy imaging, with greater coverage of a detectable metabolome, with potentially single ion level sensitivity.

### BRIEF DESCRIPTION OF THE DRAWINGS

Embodiments of the present invention are described below, by way of example only, with reference to the accompanying drawings, in which:

FIG. 1 is a schematic diagram of Orbitrap apparatus useful in the understanding of approximate Orbitrap impedance calculations (gap);

FIG. 2 this shows a cross-section of an example Orbitrap;

FIG. 3 shows a variety of pulses that can be injected into the system to measure the output voltage across the gap;

FIG. 4 is a schematic diagram of an equivalent orbitrap circuit according to the teachings herein;

FIGS. 5 and 6 show an arbitrary waveform beat signal between 1.25 and 1.27 MHz sine waves, (4096 samples) that can be applied to the circuit;

FIG. 7 is a circuit diagram of an example of cryogenic system applicable to the teachings herein;

FIGS. 8 and 9 are graphs showing signal to noise ratio at different temperatures;

FIGS. 10 and 11 are graphs showing mixer linearity over a frequency change from 1.28 MHz to 6.4 MHz;

FIGS. 12 and 13 depict an example assembly for testing the principles taught herein;

FIG. 14 is a graph showing signal and noise in the spectrum;

FIG. 15 is a schematic diagram of an embodiment of assembly;

FIG. 16 illustrates key aspects of the key apparatus and system elements of the teachings herein and

FIG. 17 is a schematic diagram of another embodiment of assembly which does not make use of a signal up-conversion unit between the spectrometer and the SQUID receiver.

### DESCRIPTION OF THE PREFERRED EMBODIMENTS

Mass spectrometry is a powerful analysis method, however key factors like sensitivity can limit its use. Increasing the sensitivity can improve speed (decreasing cost) for a given signal to noise and can improve the limit of detection in areas such as proteomics and metabolomics. Proteomics and metabolomics are moving to single-cell analysis. The small volumes of material make the measurements extremely challenging so that improved sensitivity is of paramount importance.

For instance, high-performance mass spectrometry is used intensively in the pharmaceutical industry for the identification of biological targets (proteins), understanding of drug-target interactions, measurement of drug metabolism and pharmacokinetics and accelerating the discovery of new efficacious medicines. Single cell-omics are now a major focus and given the small cell size and low abundance of biomolecules, this represents a new critical measurement challenge. Fourier Transform Mass Spectrometers (FTMS), such as the Orbitrap, are popular owing to their high mass accuracy and mass resolving power. These attributes are fundamental to unambiguous identification of a molecule in the biological milieu. The life-science sector including cancer biology, antimicrobial resistance, neurodegenerative diseases and the pharmaceutical sector is the biggest user of high-performance mass spectrometry instruments. However, FTMS instruments rely on analogue amplification of the charge for ion detection, limiting the noise floor to around 10 ions. A key metrology challenge is to make the detection work over a wide frequency range, necessary for mass spectrometry (mass ∞ frequency^{-1/2}). Other types of FTMS such as FT Ion Cyclotron Resonance Mass Spectrometry (FT ICR-MS) use a similar ion detection scheme also the noise floor to around 10 ions.

The preferred embodiments disclosed herein replace the traditional charge detection approach with a Superconducting Quantum Interference Device (SQUID), realising a Quantum-Orbitrap (Q-Orbitrap), to reach single ion sensitivity, an order of magnitude boost in sensitivity over existing devices.

The SQUID detection system disclosed herein is compatible with the impedance and capacitance of an Orbitrap. It also provides test measurements in a simplified, but electrically equivalent, Orbitrap detector. It could be applied to FT ICR-MS instruments.

An Orbitrap Fourier Transform Mass Spectrometer (FTMS) involves the production of broad bandwidth voltage signals from a high impedance (capacitive) source. On the other hand, a SQUID has a very low input impedance, which is essentially inductive. The two devices present incompatibilities, which the inventors have determined how to resolve.

Two primary approaches were considered:
a) use of a conventional radio frequency transformer at room temperature;
b) use of a cryogenic microwave resonator with appropriately matched coupling ports.

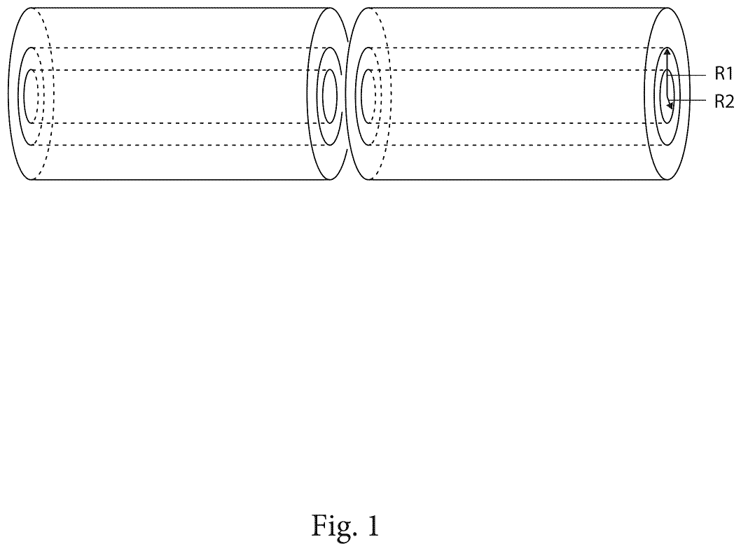

For two coaxial cylinders with outer and inner radii as shown in FIG. 1, the capacitance c and inductance l per unit length are:

$$c = 2 π {ε}_{r} {ε}_{0} ln ( \frac{{R}_{2}}{{R}_{1}} )$$

$$l = \frac{{μ}_{0}}{2 π} ln ( \frac{{R}_{2}}{{R}_{1}} )$$

Also necessary is the gap capacitance, where t is the thickness of the outer electrode wall and g is the physical gap parameter. Using R₂=20 mm, t=2 mm and g=1 mm the estimated gap capacitance can be represented by

$${C}_{g} = \frac{2 {πε}_{0} {R}_{2} t}{g} = 2.2 pF$$

With a length=10 cm, l~2.1×10⁻⁷, the inductance of each of the coaxial sections can be estimated to be

$${L}_{c} = Uxl = 2 \times {10}^{- 8} H and {C}_{c} = 6 pF .$$

The above illustrative figures predict the Orbitrap's internal resonant frequency to be

$${f}_{r} = \frac{1}{2 π} {( \frac{1}{{L}_{c} {C}_{c}} )}^{1 / 2} ∼ 500 MHz$$

The Orbitrap's characteristic impedance, treated as a length of coaxial line, Z_{c}, is

$${Z}_{c} = {( \frac{{L}_{c}}{{C}_{c}} )}^{1 / 2} = 57 ohms$$

### More Detailed Impedance Calculations

In this case, considering a variable shape of inner and outer conductors, the characteristic impedance can be expressed as:

$$Z = \frac{1}{2 π} \sqrt{\frac{μ}{ε}} ln \frac{{R}_{2}}{{R}_{1}}$$

where R₁ and R₂ are the different functions of position, R₁(x) and R₂(x), respectively.

Assuming the open ends of the cylinders do not radiate and the coaxial structure has been uniformly sliced to k sections, with a length of each section being U, the position range x is

$$[ - \frac{kU}{2} , \frac{kU}{2} ] .$$

The input impedance of the first sliced coaxial structure (left end of transmission line as seen in FIG. 1, close to air/vacuum) can be expressed as:

$${Z}_{in , 1} = {Z}_{1} \frac{{Z}_{air} + {jZ}_{1} tan β U}{{Z}_{1} + {jZ}_{air} tan β U} = {Z}_{1} \frac{1 + \frac{{jZ}_{1}}{{Z}_{air}} tan β U}{\frac{{Z}_{1}}{{Z}_{air}} + j tan β U}$$

$${Z}_{1} = \frac{1}{2 π} \sqrt{\frac{μ}{ε}} ln \frac{{R}_{2} ( - \frac{( k - 1 ) U}{2} )}{{R}_{1} ( - \frac{( k - 1 ) U}{2} )}$$

$$β = 2 π f \sqrt{{L}_{pul} {C}_{pul}} = 2 π f \sqrt{ε μ}$$

This results in:

$${Z}_{i n , 1} = {Z}_{I} \frac{1}{j tan β U} = \frac{l}{2 π j tan β U} \sqrt{\frac{μ}{ε}} ln \frac{{R}_{2} ( - \frac{( k - 1 ) U}{2} )}{{R}_{1} ( - \frac{( k - 1 ) U}{2} )}$$

After calculating the first sliced section, the same principle can be used to calculate the second, third, and so forth until the k^{th} sliced section.

The total input impedance of the open end coaxial structure is the input impedance of the last sliced section and can be determined by:

$${Z}_{in} = {Z}_{in , k} = {Z}_{k} \frac{{Z}_{k - 1} + {jZ}_{k} tan β U}{{Z}_{k} + {jZ}_{k - 1} tan β U}$$

Exact input impedance can be approximated by minimizing the length of U.

From this, the lumped element matching circuit can be derived from a Smith chart.

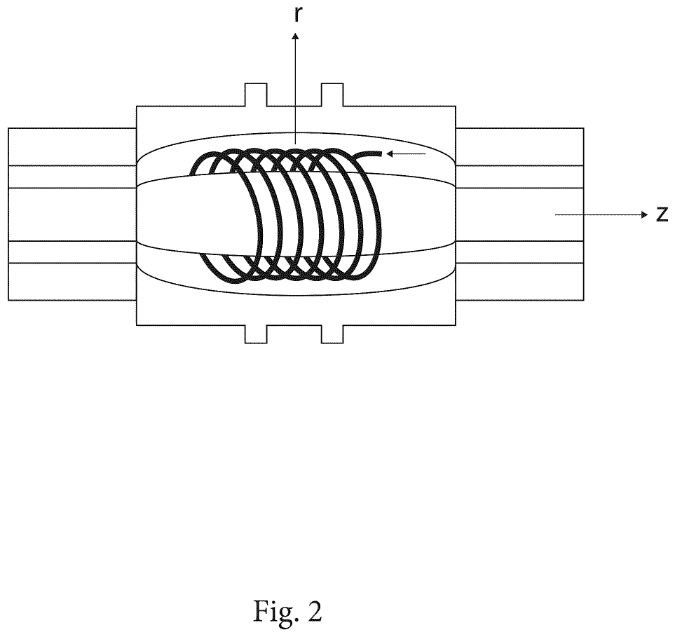

Referring now to FIG. 2, this shows a cross-section of an example Orbitrap, with a simulation of an ion track, showing the axial oscillation superimposed on a rotational orbit. The Orbitrap is an ion trap mass analyser comprising an outer barrel-like electrode and a coaxial inner spindle-like electrode that traps ions in an orbital motion around the spindle. Image current from the trapped ions is detected and converted to a mass spectrum by first using a Fourier transform of time domain of the harmonic to create a frequency signal which is converted to mass.

The induced current in the outer electrode can be simulated by inserting an off-axis coil, covering half the length of the Orbitrap. When a radio frequency current pulse is applied to the coil, it will induce inductive current flow in the half electrode, giving rise to a radio frequency voltage across the gap, similar to the induced image currents from an ion.

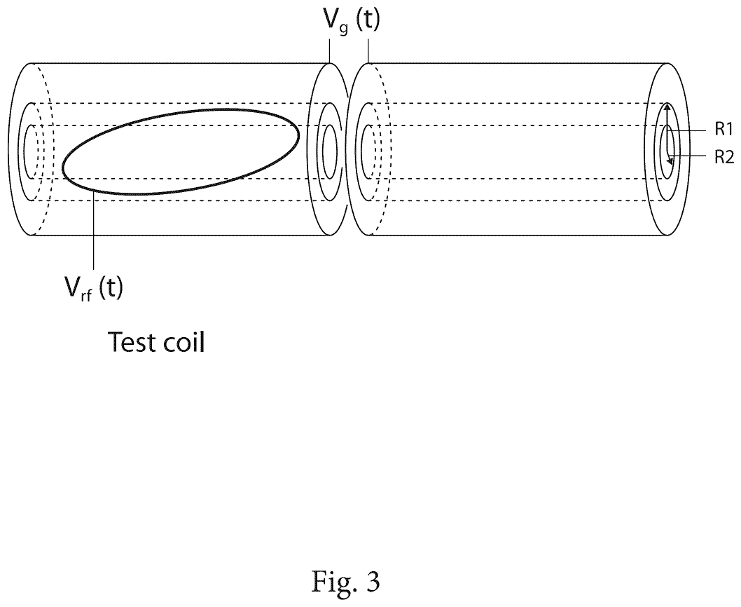

Using this coil, a variety of pulses can be injected into the system to measure the output voltage across the gap. This is shown schematically in FIG. 3.

Equation (1) below calculates the image charge Q induced on the electrode due to a charge q(r, φ, z) arising from a single ion at that point.

$$Q / q = - ( Δ Φ ( r , q , z ) / Δ U ) \qquad ( 1 )$$

where ΔΦ is the voltage induced at that same point due to a change of voltage ΔU on the electrode.

From this, the induced current at the gap l(t) can be calculated:

$$I ( t ) = \frac{dQ}{dt} = - \frac{q}{Δ U} [ \frac{\partial Δ Φ ( r , z )}{\partial r} \dot{r} + \frac{\partial Δ Φ ( r , z )}{\partial z} \dot{z} ] \qquad ( 2 )$$

$$I ( t ) \approx \frac{q}{Δ U} N \frac{\partial Δ Φ ( r , 0 )}{\partial z} \dot{z} \approx - q N ω \frac{Δ z}{λ} sin ( ω t ) \qquad ( 3 )$$

An effective induced current can be introduced using a short loop of wire inserted along the Orbitrap axis, close to the electrode gap, into which radio frequency current can be injected at a single or multiple frequencies.

For a single ion (N=1), charge e, and for the ratio of the z axis movement to the effective electrode gap ~Δz/λ~1, that is:

$$I ( t ) ∼ e ω sin ( ω t ) ∼ 10 pA$$

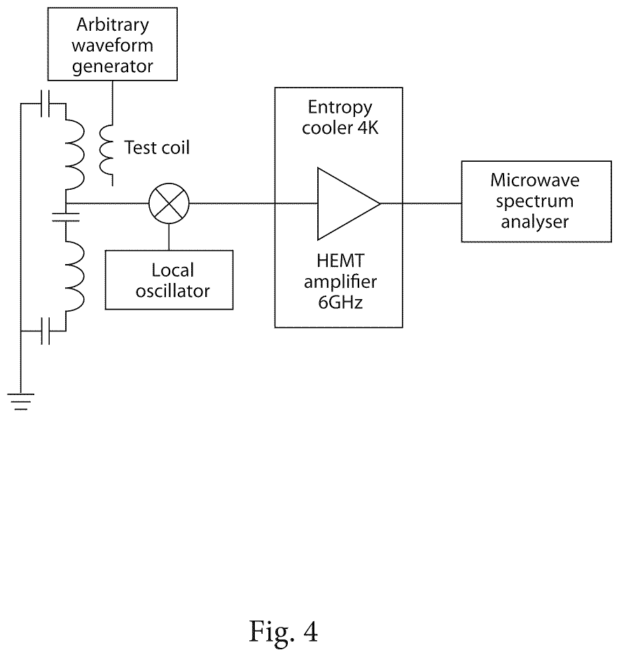

FIG. 4 is a schematic diagram of an equivalent Orbitrap circuit according to the teachings herein. The calculated output impedance of the Orbitrap means that a matching transformer at room temperature is unlikely to be required.

The circuit diagram comprises an arbitrary waveform generator 100 coupled to a test coil 102, the output of which is combined with that of a local oscillator 104 into the input of an HEMT amplifier 106, in this example operating at 6 GHZ. The amplifier 106 is held at a cryogenic temperature, preferably 4 kelvin, in a cryocooler 108. The output of the amplifier 106 is passed to a microwave spectrum analyser 110, located at ambient temperature in this example.

As can be seen in FIG. 4, the voltage across the Orbitrap gap is connected to the IF input of a microwave upconverting mixer. The local oscillator input 104 is driven by a microwave synthesiser at frequency of around 7 to 2 GHz.

The mixer radio frequency output is fed to the input of a cryogenic HEMT microwave amplifier 106, in this example held at around 10 K in pulse tube cryocooler 108 (such as a Cryomech™ cooler). The amplifier output is fed to a microwave spectrum analyser 110.

In general terms, the principle for optimising Orbitrap sensitivity disclosed herein involves injecting a broadband signal (typically in the range from ~0.5 to 1.5 MHz) from the Orbitrap and upconverting that to a microwave frequency, then suitably transforming impedance for input to a microwave SQUID at 4K.

Up-conversion can be carried out with a semiconductor microwave mixer. Such mixers tend to introduce some conversion loss (typically less than 5 dB).

Since up-conversion is a non-linear process, it is necessary to verify that the amplitude of individual radio frequency signals (for example from a single ion mass) is not compromised by mixing with near neighbour signals.

Another approach involves the use of the non-linear properties of a planar superconducting resonator, which can reduce noise and conversion loss.

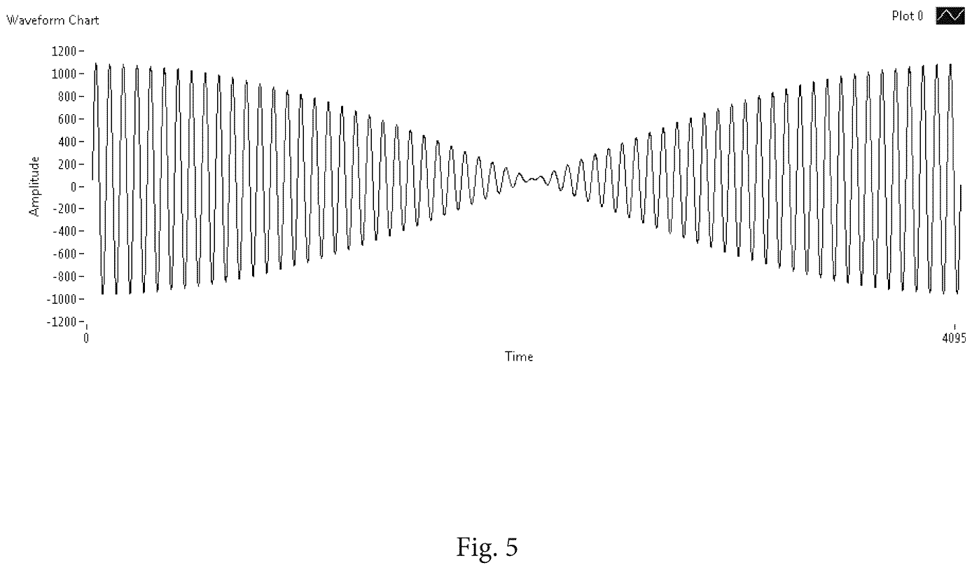

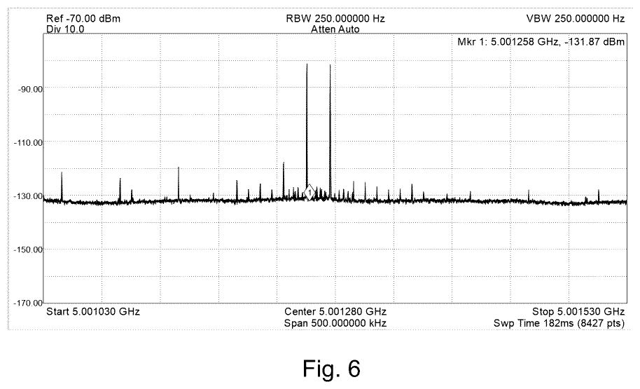

FIGS. 5 and 6 show an arbitrary waveform beat signal between 1.25 and 1.27 MHz sine waves, (4096 samples) that can be applied to the circuit.

### Cryogenic System Setup

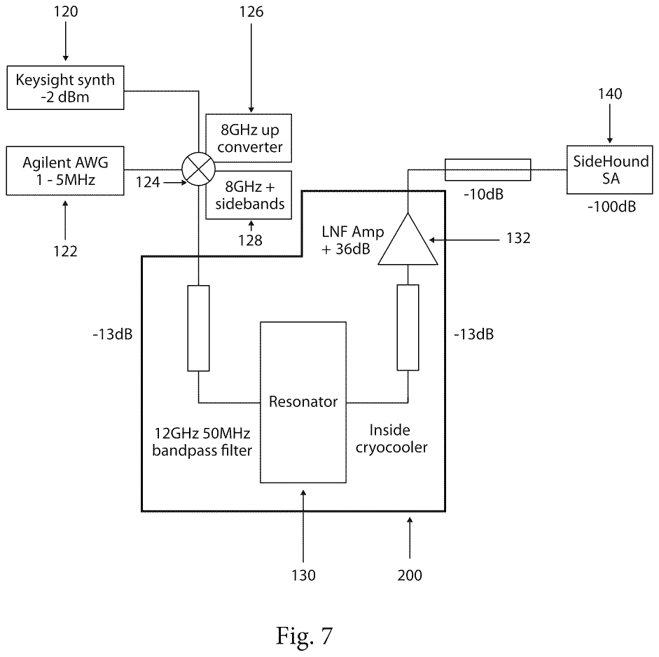

FIG. 7 is a circuit diagram of an example cryogenic system applicable to the teachings herein.

The apparatus includes as a LO (local oscillator) input to microwave mixer 124 a precision microwave synthesised source (such as a Keysight^{(RTM)} microwave synthesised source) 120. Also coupled to the mixer 124 is an arbitrary waveform generator 122 (preferably but not exclusively an Agilent^{(RTM)} 33250A). At the mixer 124 there is provided an 8 GHz upconverter 126 such that the signals are upconverted as sidebands of 8 GHZ (128). These components are disposed outside the cryocooler, typically at ambient temperature.

Disposed within a cryocooler 200 is a 12 GHz 50 MHz bandpass filter 130 coupled at its output to a Low Noise Factory amplifier providing, in this embodiment, a gain of +36 dB. The output of the LNF amplifier 132 is passed out of the cryocooler 200, typically back to ambient temperature. The amplifier output is coupled to a spectrum analyser 140, in this embodiment a SignalHound SA spectral amplifier.

The schematic diagram shows presence of attenuation in the circuit, making it possible to estimate the minimum detectable power from the IF input to the upconverter 130. The input and output coupling to the resonator are assumed to be equal. The arbitrary waveform generator 122 (preferably but not exclusively an Agilent^{(RTM)} 33250A) produces two closely spaced MHz signals, which are up converted as sidebands on the 12 GHz local oscillator signal 130.

The spectrum analyser 140 (preferably a signalHound spectrum analyser) shows the LO and sidebands on a noise floor spectrum, as depicted in FIG. 9 below.

### Comparison of the System at Room Temperature and at 10 K

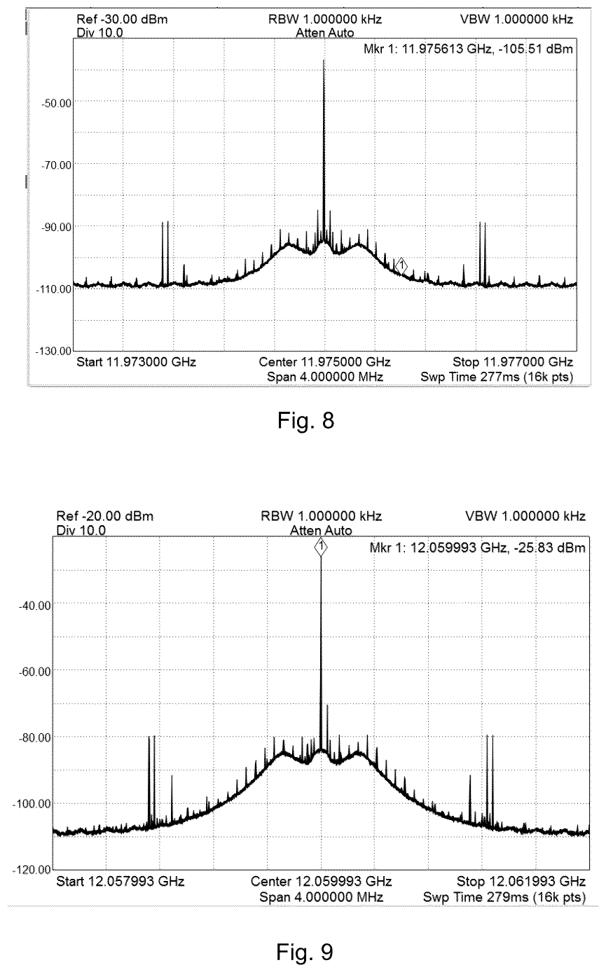

Referring to FIGS. 8 and 9, it can be seen that the signal to noise ratio improved from around 18 dB to 27 dB, which is significant. It represents the improvement in the noise temperature of the high electron mobility transistor (HEMT) amplifier when operated cold. It can be demonstrated that the up-converter does not compromise the overall gain.

### Brief Tests of Linearity, Frequency Dependence of Gain

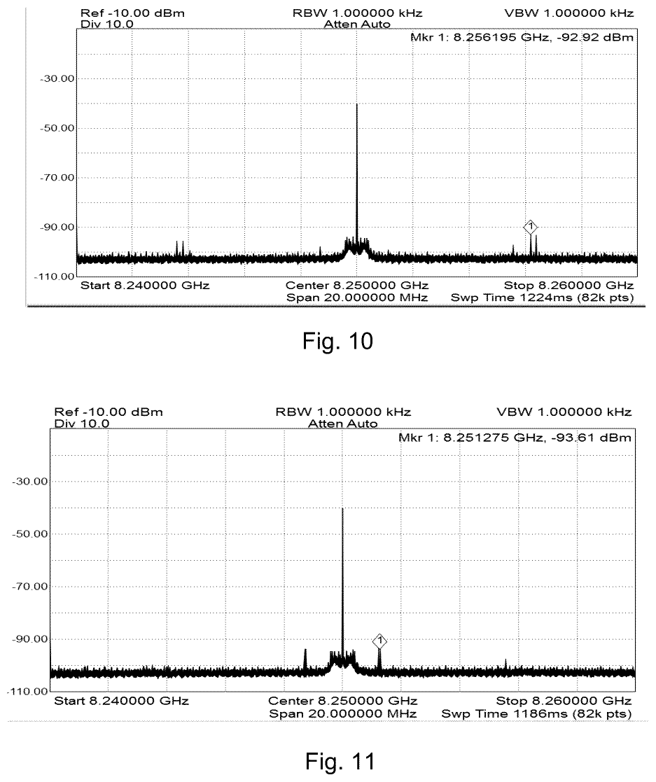

FIGS. 10 and 11 show the mixer linearity over a frequency change from 1.28 MHz to 6.4 MHz. As will be appreciated, good linearity is also achieved

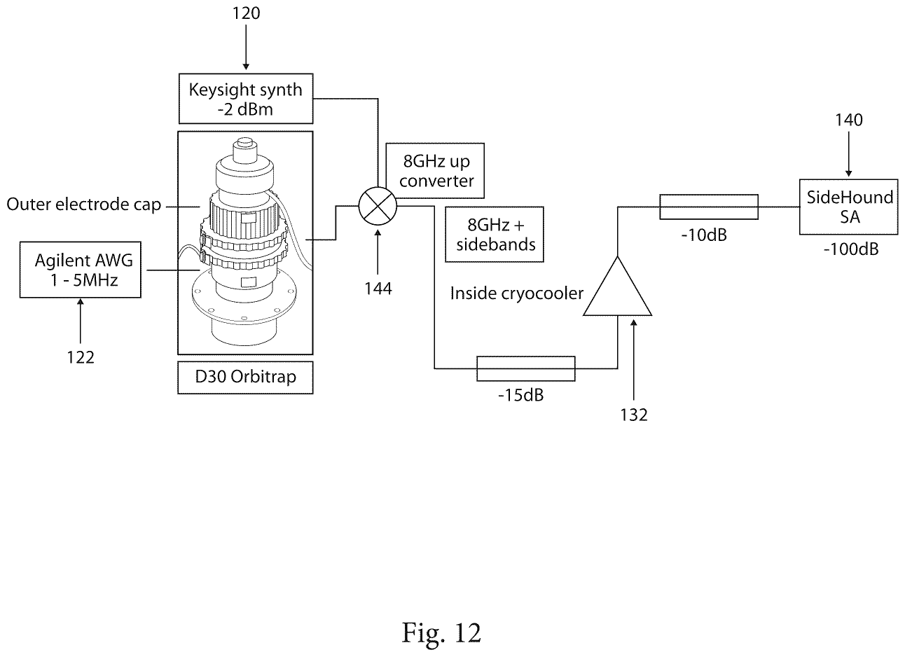

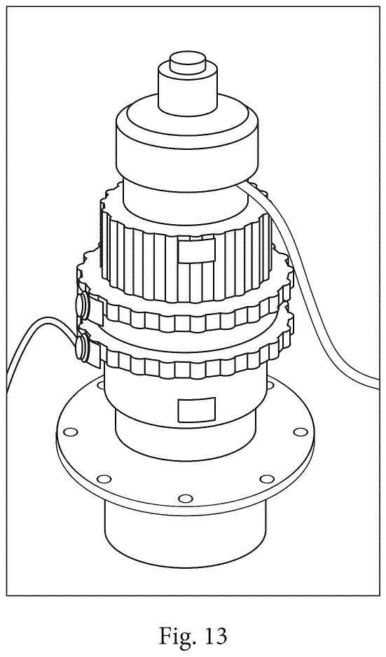

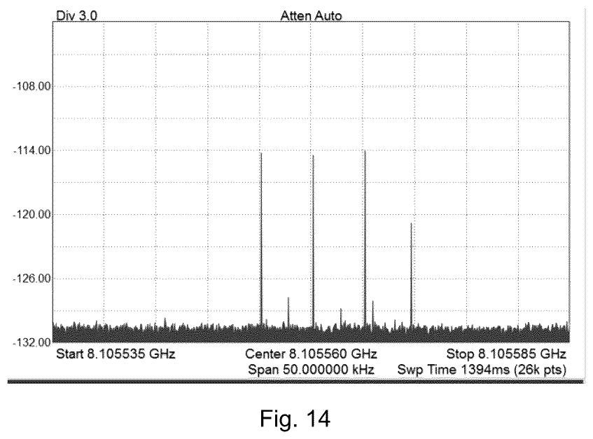

With reference to FIGS. 12 and 14, these depict an example assembly for testing the principles taught herein, specifically the up-conversion microwave detection system, consistent with the system depicted in FIG. 7.

The Orbitrap electrode system in this example comprises a Thermo-Fisher D30 Orbitrap electrode. The Orbitrap has a 30 μm gap in the outer electrode, across which a coaxial cable was connected as input to the mixer IF.

A figure of 8 coil formed from a single loop of copper wire is inserted in the space between the outer and inner electrodes of the Orbitrap, with the cross-over of the figure-8 aligns with the gap. The coil input is from the arbitrary waveform generator, described above. The LO input to the microwave mixer is provided by a precision microwave synthesised source (such as a Keysight^{(RTM)} microwave synthesised source).

The RF output from the mixer was fed to the HEMT low noise microwave amplifier, the output being fed to a room temperature spectrum analyser. Measurements were taken at room temperature and at low temperature (below 10 K) as summarised below.

The resonant filter used in the circuit described above has been removed at this stage.

### Results

The spectrum showed three equal amplitude signals, 5 kHz apart.

| LO | LO | Rf | Rf V pp | | AWG | f1 | f2 | F3 | | Temp |
|---|---|---|---|---|---|---|---|---|---|---|
| frequency | amplitude | frequency | amplitude | Attenuation | length | MHz | MHz | MHz | Average | (K) |
| 8.103 GHz | −2.0 dBm | 5 kHz | 0.025 | 60 dB | 2048 | 2.56 | 2.555 | 2.565 | 100 | 9.87 |

With reference to FIG. 14, the signal-to-noise ratio shown in the spectrum suggests that it is possible to detect MHz frequencies signals with a current amplitude of around 850 pA, even with the basic set-up shown in FIG. 12. This corresponds to around 80 ions. Much better resolution can be achieved with the use of a SQUID configured as taught herein.

### Addition of a SQUID

Although SQUIDs have already found wide ranging applications in single quantum detection systems they have not previously been envisaged as a suitable detector for Fourier Transform mass spectrometry of ions.

SQUIDS have previously been used in an ion trap and demonstrated the ability to achieve single ion sensitivity. However, this was limited to operating at one frequency (and one mass) and not for a spectrum of masses as required in a mass spectrometer.

The system disclosed herein proposes a new arrangement in which a SQUID microwave receiver, held at cryogenic temperature, takes the broadband radio frequency signal output from an Orbitrap mass spectrometer operating at room temperature. By suitable impedance transformation and signal up-conversion, the much lower noise temperature of the SQUID amplifier can be used to reduce the overall signal to noise performance of the Orbitrap compared to a conventional analogue amplifier readout system. The inventors have determined that this can lead to a ten-fold improvement in signal to noise and the ability to detect single ions.

Additionally, the high impedance MHz frequency ion signal emerging from the room temperature Orbitrap sensor is matched to the low impedance cryogenic SQUID system without adding significant noise to the system.

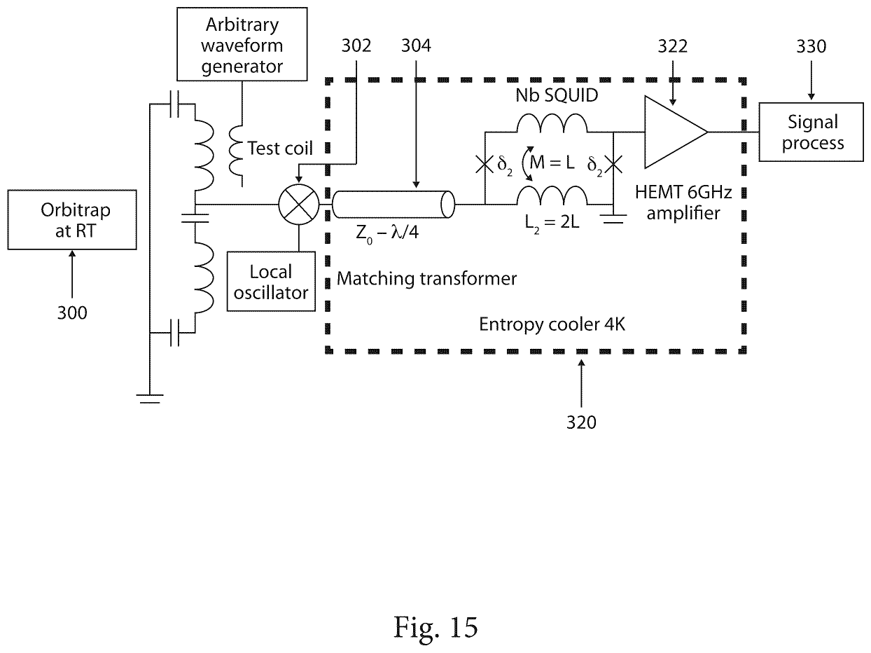

A schematic diagram of an embodiment of assembly is shown in FIG. 15. The circuit shows an Orbitrap equivalent circuit 300 (at room temperature) coupled to an upconverting mixer 302 and then to a matching transformer 304 and a SQUID sensor 310 held at 4K in an entropy cryocooler 320. The SQUID output is fed through an HEMT 6 GHz amplifier 322 (in this embodiment) to a signal processing unit 330, at room temperature.

The preferred SQUID uses niobium (Nb) superconducting thin films, typically 50 to 200 nm in thickness, exhibiting superconducting transition temperatures between 8.2 and 9.0 K. For microwave circuit components and interconnections, the films are typically patterned into coplanar waveguide (CPW) structures using photo-lithographic or electron beam lithography (EBL) techniques. Microwave resonators in the frequency range from 1 GHz to 30 GHz are patterned on a typical 1 cm square silicon chip. This chip size provides ample space for integrated resonator and SQUID structures with enough real estate to allow multiple designs to be tested in a single fabrication run.

Single or multiple SQUID devices can be patterned onto the same chip using either EBL or focussed ion beam (FIB) milling to provide the required superconducting loop and its incorporated Nb nanobridge restrictions which form Josephson junctions. Such fabrication technology has demonstrated some of the lowest noise SQUID devices operating at 4 K (L Hao et al., Applied Physics Letters 92 (19), 192507). The energy sensitivity has been shown to be as low as 30 ℏ, even at an operating temperature up to 7 K. This results in microwave superconducting circuits incorporating SQUIDs as the first ultralow noise amplification stage in the chain. A second stage is based on a high electron mobility transistor (HEMT) cryogenic amplifier with a typical noise temperature of a few kelvin. The remainder of the necessary signal processing, that is data collection and Fourier transform analysis, can be carried out at room temperature and can be based on a combination of fast analogue to digital conversion combined with signal processing used in existing Orbitrap instruments.

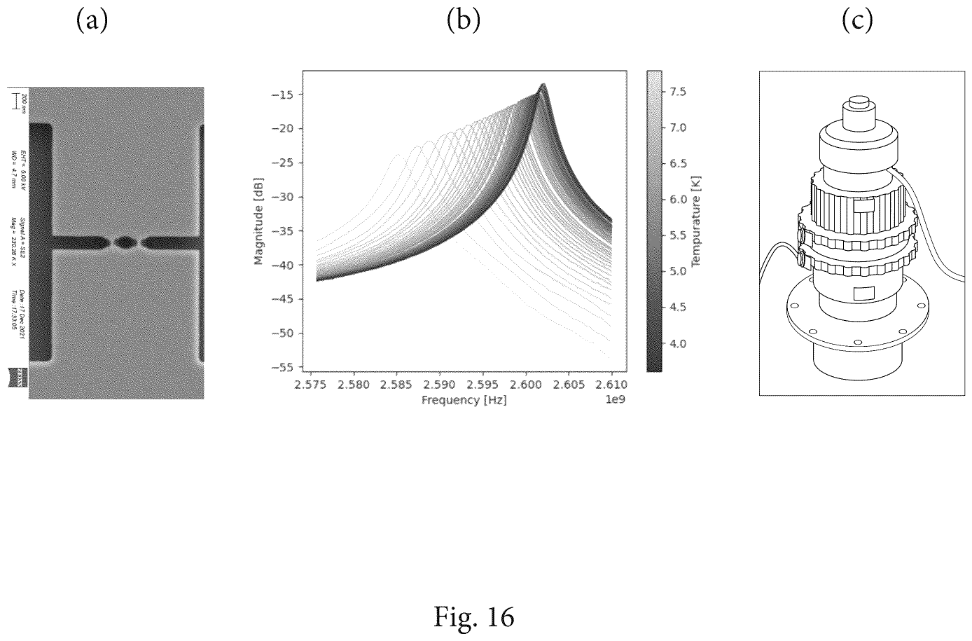

FIG. 16 illustrates important aspects of the key technology innovations.

FIG. 16a) is an SEM image of a Nb nanoSQUID. FIG. 16b) is an image of the half wavelength 2.5 GHz CPW superconducting Nb resonator showing high quality factor over a range of temperature. FIG. 16c) shows a bare Orbitrap coupled to cryogenic HEMT amplifier operating at 8K.

Using a bare Orbitrap, it has already been shown that it is possible to couple the Orbitrap output electrodes via an up-converting mixer to a cryogenic environment containing a low noise high electron mobility transistor (HEMT) amplifier. Simulated ion signals in the frequency range from 1 MHz to 5 MHz have been applied to the Orbitrap electrodes and improved signal to noise from the HEMT output has been demonstrated when operated at cryogenic temperature. It is believed that a state-of-the-art SQUID microwave amplifier and superconducting CPW impedance transformer at the start of the receiver chain could realise single ion detection sensitivity.

The assembly preferably uses microwave SQUIDs based on Josephson junctions using superconducting nano-constrictions (nano Dayem bridges).

The Orbitrap Fourier Transformer Mass Spectrometer 330 involves the production of broad bandwidth voltage signals from a high impedance (capacitive) source, whereas the SQUID 310 has a very low input impedance, essentially inductive. The use of high frequency transformer-based impedance transformation is modelled to allow maximum signal transfer efficiency while maintaining maximum available bandwidth.

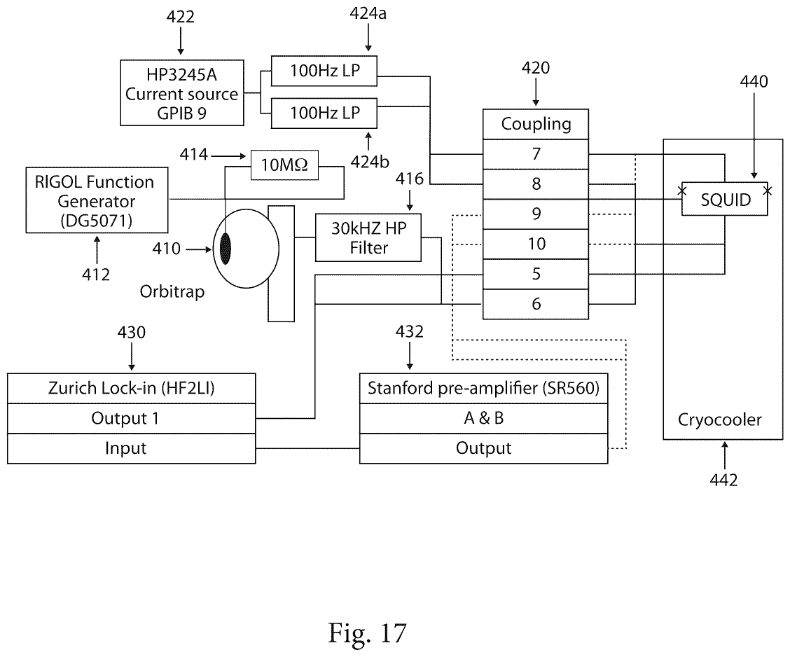

FIG. 17 shows an embodiment of circuitry which does not make use of a signal-up conversion unit.

The apparatus of FIG. 17 comprises an Orbitrap spectrometer 410 having a prober connected to a RIGOL Waveform Function Generator 412 (in this example model DGS071), which may be connected directly to the Orbitrap 410 or through a 10 Megaohm resistance 414. The output of the Orbitrap 410 is connected through a 30 KHz HP filter 416 to a coupling manifold 420.

A current source 422, in this example an HP3245A Current Source GBIB 9, is coupled through one or more 100 Hz LP filters 424a, 424b to the coupling manifold 420.

A Lock-in Amplifier 430 (in this example a Zurich 50 MHz Lock-in Amplifier HF2LI), has an output connected to the coupling manifold 420 and an input connected to a pre-amplifier 432 (in this example a Stanford model SR560), itself connected to the coupling manifold 420.

A SQUID 440, disposed in a cryocooler 442, is connected through the coupling manifold 420 as shown in FIG. 17.

The embodiment of apparatus shown in FIG. 17 does not make use of an up-converter unit between the spectrometer 410 and the SQUID 440, although it is not excluded that an up-converter could be provided in other embodiments.

The disclosure in British patent application number GB2303717.9, from which this application claims priority, and in the abstract accompanying this application are incorporated herein by reference.

1. A spectrometer assembly comprising:
a spectrometer disposed in an ambient temperature environment;
a SQUID microwave receiver disposed in a cryogenic enclosure; and
an impedance matching unit disposed between and coupled to the spectrometer and the SQUID receiver so as to provide impedance matching between the spectrometer and the SQUID microwave receiver.

2. An assembly according to claim 1, comprising a signal up-conversion unit, disposed between and coupled to the spectrometer and the SQUID receiver so as to provide signal up-conversion between the spectrometer and the SQUID microwave receiver.

3. An assembly according to claim 1, wherein the spectrometer is a mass spectrometer.

4. An assembly according to claim 3, wherein the mass spectrometer comprises an ion trap mass analyser comprising an outer barrel-like electrode and a coaxial inner spindle-like electrode configured to trap ions in an orbital motion around the spindle.

5. An assembly according to claim 4, wherein the mass spectrometer is an Orbitrap mass spectrometer.

6. An assembly according to claim 1, wherein the spectrometer is a spectrometer using a coil pick-up method of current at radiofrequencies.

7. An imaging assembly comprising:
an imaging device disposed in an ambient temperature environment;
a SQUID microwave receiver disposed in a cryogenic enclosure; and
an impedance matching unit disposed between and coupled to the imaging device and the SQUID receiver so as to provide impedance matching between the imaging device and the SQUID microwave receiver.

8. An assembly according to claim 7, comprising a signal up-conversion unit, disposed between and coupled to the imaging device and the SQUID receiver so as to provide signal up-conversion between the spectrometer and the SQUID microwave receiver.

9. An assembly according to claim 7, wherein the imaging device is a magnetic resonance imaging (MRI) device.

10. An assembly according to claim 1, wherein the SQUID provides a first, low noise, amplification stage in the assembly; a second stage being provided by an amplifier disposed in a cryogenic enclosure.

11. An assembly according to claim 10, wherein the second stage amplifier is a high electron mobility transistor (HEMT) cryogenic amplifier.

12. An assembly according to claim 11, wherein the high electron mobility transistor (HEMT) cryogenic amplifier is a 6 GHz amplifier.

13. An assembly according to claim 1, comprising a signal processing unit coupled to an output of the SQUID and disposed in an ambient temperature environment.

14. An assembly according to claim 1, wherein the SQUID is a microwave SQUID based on Josephson junctions using superconducting nano-constrictions.

15. An assembly according to claim 1, wherein the SQUID is a microwave SQUID based on Josephson junctions using superconducting tunnel junctions.

16. An assembly according to claim 1, wherein the SQUID is held in a cryogenic enclosure at around 4K.

17. An assembly according to claim 1, wherein the SQUID comprises niobium (Nb) superconducting thin films, typically 50 to 200 nm in thickness, exhibiting superconducting transition temperatures between 8.2 and 9.0K.

18. An assembly according to claim 17, wherein the superconducting thin films are patterned into coplanar waveguide structures, with microwave resonators in the frequency range from 1 GHz to 30 GHz.

19. An assembly according to claim 7, wherein the SQUID provides a first, low noise, amplification stage in the assembly; a second stage being provided by an amplifier disposed in a cryogenic enclosure.

20. An assembly according to claim 7, wherein the second stage amplifier is a high electron mobility transistor (HEMT) cryogenic amplifier.
